(19) United States
(12) Patent Application Publication
(10) Pub. No.: US 2012/0194215 A1
(43) Pub. Date: Aug. 2, 2012

(54) SEMICONDUCTOR APPARATUS AND IMPEDANCE CALIBRATION CIRCUIT FOR THE SAME

(75) Inventor: Chang Kyu CHOI, Icheon-si (KR)

(73) Assignee: HYNIX SEMICONDUCTOR INC., Icheon-si (KR)

(21) Appl. No.: 13/219,615

(22) Filed: Aug. 27, 2011

(30) Foreign Application Priority Data
Jan. 28, 2011 (KR) 10-2011-0009004

(51) Int. Cl. H03K 19/003

(52) U.S. Cl. 326/30

(57) ABSTRACT

A semiconductor apparatus includes a data input/output circuit and an impedance calibration circuit. The impedance calibration circuit may be configured to output a code signal for controlling a resistance value of the data input/output circuit in response to a division voltage applied to a joining interconnection directly coupled to a ZQ pad and a preset reference voltage.

### CROSS-REFERENCES TO RELATED APPLICATION

The present application claims priority under 35 U.S.C. §119(a) to Korean application number 10-2011-0009004 filed on Jan. 28, 2011 in the Korean Intellectual Property Office, and which is incorporated herein by reference in its entirety.

### BACKGROUND

1. Technical Field

The present invention relates to an integrated circuit apparatus, and more particularly, to a semiconductor apparatus and an impedance calibration circuit for the same.

2. Related Art

Semiconductor devices have been applied to an increasing number of electronic devices. As speed of the electric devices increases, the swing width of signals exchanged between the semiconductor devices has been reduced to minimize delay time during signal transfer. However, as the swing width of signals is reduced, noise susceptibility inevitably increased. Furthermore, reflection of signals caused by impedance mismatching between the semiconductor devices frequently occurs.

Such impedance mismatching is caused by PVT (process, voltage, and temperature) variations or the like. The PVT variations may disturb transmission of data and distort output data.

In order to solve such a problem, an on-die termination (ODT) circuit is applied to a semiconductor device requiring high-speed operation. The impedance mismatching problem for an output device may be solved by the ODT circuit. Therefore, the ODT circuit should be configured in such a manner as to perform resistance control. For this configuration, an impedance calibration circuit has been adopted.

FIG. 1 is a diagram explaining the operation of an impedance calibration circuit in a conventional semiconductor apparatus.

Referring to FIG. 1, a semiconductor apparatus 10 is packaged after being completely manufactured, and configured to include an impedance calibration circuit 20.

The impedance calibration circuit 20 includes a ZQ pad 101, a comparator 107, a counter 109, a first pull-up unit 111, and a register 113.

In order to perform impedance calibration, an external resistor Rext is coupled to a pin 105 outside the package, which is coupled to the ZQ pad 101 through a wire 103. Accordingly, a division voltage between a voltage applied to the ZQ pad 101 and a voltage applied to an output node K2 of the first pull-up unit 111 is inputted to the comparator 107 through the first node K1.

A reference voltage Vref is applied to the comparator 107, and the comparator 107 operates the counter 109 according to a difference between the reference voltage Vref and the voltage applied to the first node K1.

A first code signal pcode<0:n> outputted from the counter 109 is inputted to the first pull-up unit 111 to change the resistance value of the first pull-up unit 111. Accordingly, the division voltage between the voltage applied to the ZQ pad 101 and the voltage applied to the output node K2 of the first pull-up unit 111, that is, the voltage applied to the first node K1 is changed.

The counter 109 is disabled when the reference voltage Vref is equalized to the voltage applied to the first node K1, and the code signal at this time is stored in the register 113.

A second code signal pcode_{—reg<}0:n> outputted from the register 113 is provided to a second pull-up unit 115 to change the resistance value of the second pull-up unit 115, thereby calibrating a resistance value from a DQ pad 117 through a wire 191 to a pin 121.

That is, the first pull-up unit 111, the ZQ pad 101, the wire 103, and the pin 105 are provided in the impedance calibration circuit 20 configured in the same manner as an input/output circuit including the second pull-up unit 115, the DQ pad 117, the wire 119, and the pin 121. The first code signal pcode<0:n> at a time point where the voltage applied to the ZQ pad 101 is equalized to the reference voltage Vref is provided as the second code signal to the second pull-up unit 115 to thereby perform impedance matching.

FIG. 2 is a diagram explaining an influence caused by parasitic resistance in the impedance calibration circuit illustrated in FIG. 1.

Referring to FIG. 2, the first pull-up unit 111 and the comparator 107 in the conventional semiconductor apparatus are formed in a first interconnection layer M1. Furthermore, the ZQ pad 101 is formed in a third interconnection layer M3 coupled through the first interconnection layer M1, a second interconnection contact M2C, a second interconnection layer M2, and a third interconnection contact M3C.

In other words, the output node K2 of the first pull-up unit 111 is coupled to the ZQ pad 101 through the first interconnection layer M1, the second interconnection contact M2C, the second interconnection layer M2, the third interconnection contact M3C, and the third interconnection layer M3, and the comparator 107 is coupled to an interconnection diverging from the first interconnection layer M1. Finally, a division voltage at a voltage division point Pdiv between the ZQ pad 101 and the first pull-up unit 111 is inputted to the comparator 107.

Therefore, external effective resistance Rext_eff at the voltage division point Pdiv corresponds to a value obtained by adding parasitic resistance A (R_{P}_{_{—}}A) to the external resistance Rext. Furthermore, effective resistance R_pu1_eff of the first pull-up unit 111 at the voltage division point Pdiv corresponds to a value obtained by adding parasitic resistance B (R_{P}_{_{—}}B) to the resistance R_pu1 of the first pull-up unit 111. The effective resistances may be expressed as Equations 1 and 2 below.

Rext_eff=Rext+R_{P}_{_{—}}A Eq. 1

R_pu1_eff=R_pu1+R_{P}_{_{—}}B Eq. 2

Furthermore, since the first pull-up unit 111 is configured to have the same structure as that of the second pull-up unit 115, the following equation should be satisfied.

Rext=R_pu1+R_pu2 Eq. 3

Therefore, when the impedance calibration operation is completed, the resistance of the first pull-up unit 111 may be expressed as Equation 4 below.

$$\begin{matrix}R\_pu1 = Rext\_eff - {R}_{P} \_B \\ = Rext + {R}_{P} \_A - {R}_{P} \_B\end{matrix} \qquad Eq . 4$$

Meanwhile, the parasitic resistance A (R_{P}_{_{—}}A) may be expressed as Equation 5 below.

R_{P}_{_{—}}A=resistance of pin 105+resistance of wire 103+resistance of third interconnection layer M3+resistance of third interconnection contact M3C+resistance of second interconnection layer M2+resistance of second interconnection contact M2C+resistance of first interconnection layer M1 Eq. 5

Furthermore, the parasitic resistance B (R_{P}_{_{—}}B) becomes the resistance of the first interconnection layer M1.

FIG. 3 is a diagram explaining an influence caused by the parasitic resistance in the input/output circuit illustrated in FIG. 1.

Since the impedance calibration circuit 20 is configured in a similar manner to the configuration of the input/output circuit, parasitic resistance C (R_{P}_{_{—}}C) equals the parasitic resistance A (R_{P}_{_{—}}A), and parasitic resistance D (R_{P}_{_{—}}D) equals the parasitic resistance B (R_{P}_{_{—}}B).

The effective resistance R_pu2_eff of the second pull-up unit 115 may be expressed as Equation 6 below.

R_pu2_eff=R_pu2+R_{P}_{_{—}}C+R_{P}_{_{—}}D Eq. 6

According to the impedance calibration operation, the second pull-up unit 115 has the same resistance value as the first pull-up unit 111. Therefore, the effective resistance R_pu2_eff may be expressed as Equation 6 below.

$$\begin{matrix}R\_pu2 \_eff = R\_pu1 + {R}_{P} \_C + {R}_{P} \_D \\ = Rext + {R}_{P} \_A - {R}_{P} \_B + {R}_{P} \_C + {R}_{P} \_D \\ = Rext + 2 {R}_{P} \_A \\ = Rext + 2 {R}_{P} \_C\end{matrix} \qquad Eq . 7$$

Accordingly, it can be seen that the effective resistance of the second pull-up unit 115 may be larger by as much as 2R_{P}_{_{—}}A or 2R_{P}_{_{—}}C than the external resistance Rext, and the resistance difference may serve as an error factor after the impedance calibration operation is completed.

The error value corresponds to 2*(resistance of pin 105+resistance of wire 103+resistance of third interconnection layer M3+resistance of third interconnection contact M3C+resistance of second interconnection layer M2+resistance of second interconnection contact M2C+resistance of first interconnection layer M1), and is physically caused by the layout of the impedance calibration circuit and the input/output circuit.

As such, since the error value of the input/output circuit of the semiconductor apparatus contains all components from the pin 105 to the first interconnection layer M1, the error value is non-negligibly large. Accordingly, the semiconductor apparatus is vulnerable to a process variation.

In the current semiconductor apparatus, effective resistance at a DQ pin is different from external resistance, thereby causing the occurrence of jitter. As a result, the performance of the semiconductor apparatus may be degraded. For example, the semiconductor apparatus may operate at a lower speed than expected due to the parasitic resistance. Thus, the semiconductor apparatus cannot exhibit the performance based on the design.

### SUMMARY

In one embodiment of the present invention, a semiconductor apparatus includes a data input/output circuit and an impedance calibration circuit configured to output a code signal for controlling a resistance value of the data input/output circuit in response to a division voltage applied to a joining interconnection directly coupled to a ZQ pad and a preset reference voltage.

In another embodiment of the present invention, an impedance calibration circuit includes a first pull-up unit coupled to a ZQ pad, a joining interconnection directly electrically coupled to the ZQ pad, and a comparator configured to generate a code signal in response to a division voltage applied to the joining interconnection and a preset reference voltage, and provide the generated code signal to the first pull-up unit and a data input/output circuit.

In another embodiment of the present invention, an impedance calibration circuit of a semiconductor apparatus includes a ZQ pad, a first pull-up unit coupled to the ZQ pad through a first electrical path,; and a comparator coupled to the ZQ pad through a second electrical path, wherein the comparator is configured to compare a voltage, dependent upon the pull-up unit, with a reference voltage, and wherein the first electrical path and the second electrical path have a common node only at the ZQ pad.

### BRIEF DESCRIPTION OF THE DRAWINGS

Features, aspects, and embodiments are described in conjunction with the attached drawings, in which:

FIG. 1 is a diagram explaining the operation of an impedance calibration circuit in a conventional semiconductor apparatus;

FIG. 2 is a diagram explaining an influence caused by parasitic resistance in the impedance calibration circuit illustrated in FIG. 1;

FIG. 3 is a diagram explaining an influence caused by the parasitic resistance in an input/output circuit illustrated in FIG. 1;

FIG. 4 is a layout diagram of an impedance calibration circuit according to one embodiment; and

FIG. 5 is a layout diagram of an output apparatus in a semiconductor apparatus to which the impedance calibration circuit illustrated in FIG. 4 is applied.

### DETAILED DESCRIPTION

A semiconductor apparatus and an impedance calibration circuit for the same according to the present invention will be described below with reference to the accompanying drawings through exemplary embodiments.

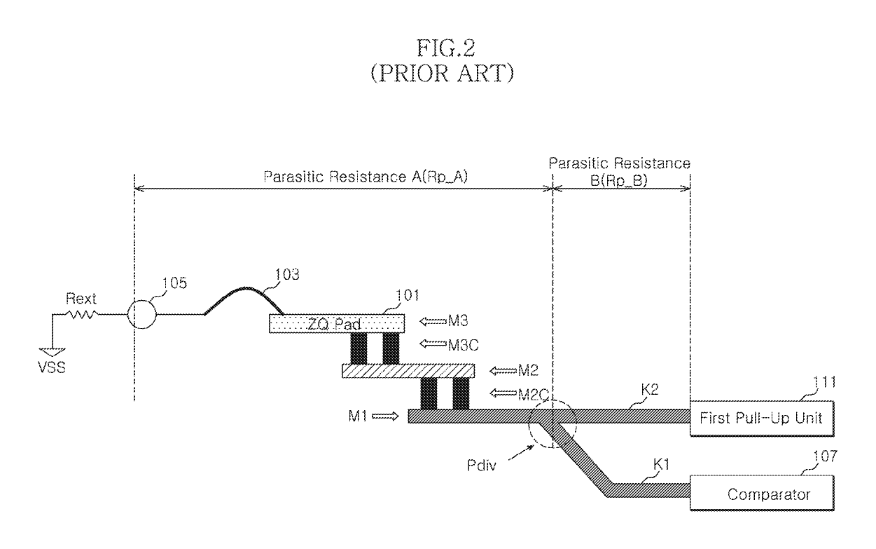

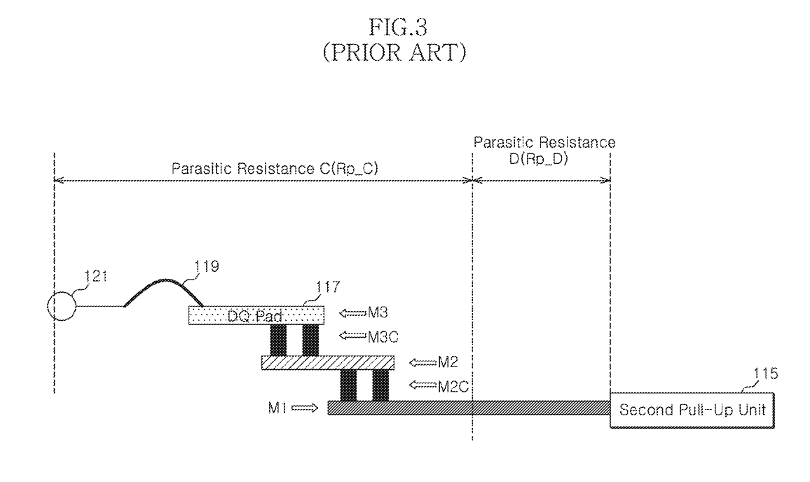

As described above, the resistance difference between the external resistor Rext and the DQ pin is proportional to the component of the parasitic resistance A or C (refer to FIGS. 2 and 3). The parasitic resistance A or C is determined by the layout from the external resistor Rext to the voltage division point Pdiv between the ZQ pad 101 and the first pull-up unit 111. In particular, as the distance from the external resistor Rext to the voltage division point Pdiv increases, the parasitic resistance may also increase. Then, the error value also increases.

Accordingly, an embodiment of the present invention provides a method capable of minimizing the parasitic component existing between the external resistor Rext and the voltage division point Pdiv between the ZQ pad 101 and the first pull-up unit 111.

Embodiments of the present invention will be described with reference to the accompanying drawings.

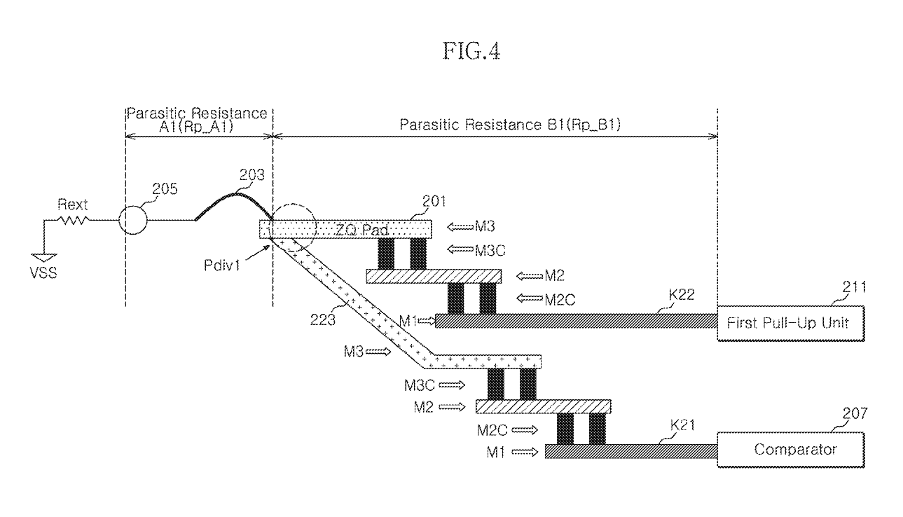

FIG. 4 is a layout diagram of an impedance calibration circuit according to one embodiment.

Referring to FIG. 4, the impedance calibration circuit according to the embodiment includes an external resistor Rext having an end coupled to a ground terminal VSS, a ZQ pin 205 coupled to the other end of the external resistor Rext, a ZQ pad 201 coupled to the ZQ pin 205 through a wire 203, a first pull-up unit 211 coupled to the ZQ pad 201 through first to third interconnection layers M1, M2, M3, and a comparator 207 coupled to the ZQ pad 201 through a joining interconnection 223 and the first to third interconnection layers M1, M2, M3.

Electrical conductivity in the first to third interconnection layers M1, M2, M3 may be due intrinsic conductivity of those layers. Electrical conductivity may also be due to conductive material such as, for example, a metal line, in and/or on the first to third interconnection layers M1, M2, M3. If metal lines are used, the first to third interconnection layers M1, M2, M3 may be non-conductive. The joining interconnection 223 may also comprise a metal line. The specific method of forming conductive paths in the interconnection layers M1, M2, M3 and the joining interconnection 223 may be design and/or implementation dependent.

FIG. 4 illustrates that the ZQ pad 201 and the comparator 207 are coupled through the first to third interconnection layers and the joining interconnection 223, but the configuration is not limited thereto. That is, the joining interconnection 223 may be directly extended from a layer in which the comparator 207 is formed to a layer in which the ZQ pad 201 is formed, thereby electrically coupling the comparator 207 to the ZQ pad 201.

A division voltage between a voltage applied to the ZQ pad 201 and a voltage applied to an output node K22 of the first pull-up unit 211 is applied to an input node K21 of the comparator 207 by the external resistor Rext, and the comparator 207 compares a reference voltage with the division voltage to control a counter (not illustrated).

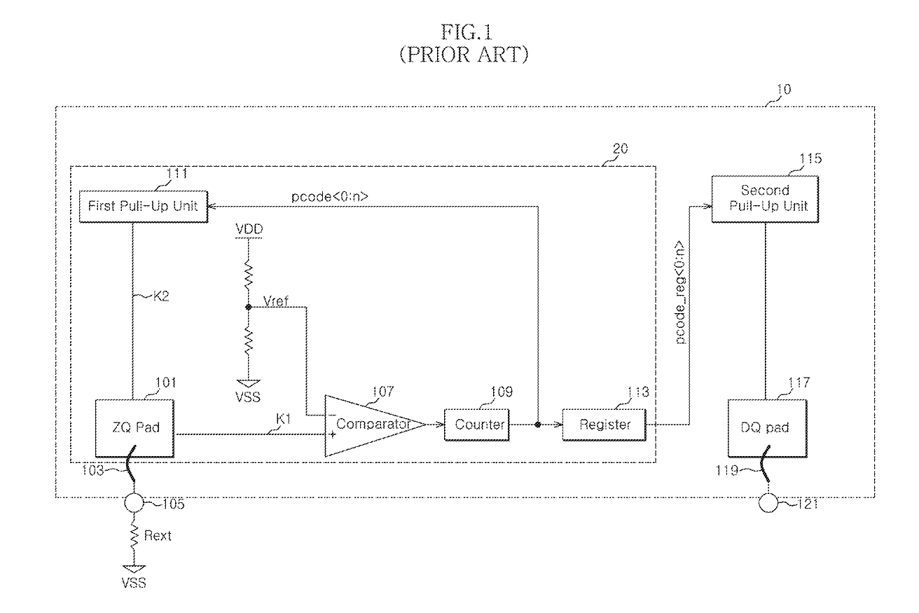

Although not illustrated, the counter is configured to control the division voltage by changing the resistance value of the first pull-up unit 211 until the division voltage is equalized to the reference voltage. Furthermore, when the division voltage is equalized to the reference voltage, a code signal at this time is provided to a second pull-up unit 215 to change the resistance value of a DQ pin 121. Accordingly, the function of the counter may be similar to the counter 109 in FIG. 1. The second pull-up unit 215 will be described below.

In particular, the ZQ pad 201 is coupled to the joining interconnection 223 diverging from the ZQ pad 201 in a layer in which the ZQ pad 201 is formed, that is, in the same layer as the third interconnection layer M3. The comparator 207 is coupled to the ZQ pad 201 through the joining interconnection 223, the third interconnection layer M3, a third interconnection contact M3C, a second interconnection contact M2C, and the first interconnection layer M1. Furthermore, the first pull-up unit 211 is coupled to the ZQ pad 201 through the third interconnection layer M3, a third interconnection contact M3C, the second interconnection layer M2, the second interconnection contact M2C, and the first interconnection layer M1.

The coupling point between the ZQ pad 201 and the joining interconnection 223 serves as a voltage division point Pdiv1 at which a voltage applied to the ZQ pad 201 and a voltage applied to the first pull-up unit 211 are divided.

Therefore, a voltage applied to the input node of the comparator 207 is decided by the resistance component before the voltage division point Pdiv1.

According to the above-described configuration, an effective external resistance value Rext_eff and an effective resistance value of the first pull-up unit 211 are decided as follows.

Rext_eff=Rext+R_{P}_{_{—}}A1 Eq. 8

R_pu1_eff=R_pu1+R_{P}_{_{—}}B1 Eq. 9

Furthermore, after an impedance calibration operation is completed, the resistance R_pu1 of the first pull-up unit 211 may be expressed as Equation 10 below.

$$\begin{matrix}R\_pu1 = Rext\_eff - {R}_{P} \_B 1 \\ = Rext + {R}_{P} \_A1 - {R}_{P} \_B1\end{matrix} \qquad Eq . 10$$

Here, parasitic resistance A1 includes resistance components of the ZQ pin 205, the wire 203, and the third interconnection layer M3. Parasitic resistance B1 includes resistance components of the third interconnection layer M3, the third interconnection contact M3C, the second interconnection layer M2, the second interconnection contact M2C, and the first interconnection layer M1.

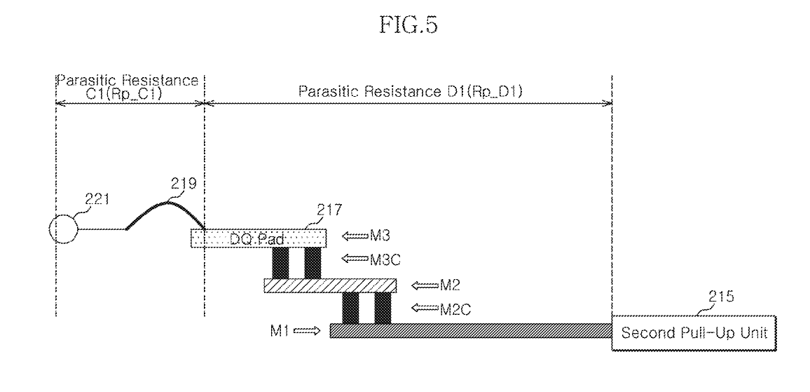

When the layout of the impedance calibration circuit is configured as illustrated in FIG. 4, an output apparatus may be configured as illustrated in FIG. 5.

FIG. 5 is a layout diagram of the output apparatus in a semiconductor apparatus to which the impedance calibration circuit illustrated in FIG. 4 is applied.

Since the input/output circuit and the impedance calibration circuit are configured to have the same layout, parasitic resistance C1 from a DQ pin 221 through a wire 219 to a DQ pad 217 is equal to the parasitic resistance A1, and parasitic resistance D1 from the DQ pad 217 to the second pull-up unit 215 is equal to the parasitic resistance B1. Therefore, effective resistance of the second pull-up unit 215 may be expressed as Equation 11 below.

$$\begin{matrix}R\_pu2 \_eff = R\_pu1 + {R}_{P} \_C1 + {R}_{P} \_D 1 \\ = Rext + {R}_{P} \_A 1 - {R}_{P} \_B1 + {R}_{P} \_C1 + {R}_{P} \_D1 \\ = Rext + 2 {R}_{P} \_A1 \\ = Rext + 2 {R}_{P} \_C 1\end{matrix} \qquad Eq . 11$$

In Equation 11, an error value (2R_{P}_{_{—}}A1=2R_{P}_{_{—}}C1) is caused by the parasitic resistance A1 or C1, and includes substantially the same components, that is, the resistance components of the ZQ pin 205, the wire 203, and the third interconnection layer M3.

In this embodiment, the input node to the comparator 207 is divided on the ZQ pad 201, which makes it possible to reduce the distance from the external resistor Rext to the voltage division point Pdiv1. In other words, since an error value is decided by components existing on the voltage division point Pdiv1, the resistance difference between the external resistor Rext and the DQ pin 221 is minimized by a method of minimizing the parasitic resistance component before the voltage division point Pdiv1.

Compared with the conventional semiconductor apparatus, it is possible to remove an influence caused by the resistance components included in the third interconnection contact M3C, the second interconnection layer M2, the second interconnection contact M2C, and the first interconnection layer M1, thereby minimizing an error value variation caused by a process variation or the like. In short, in the impedance calibration circuit, the voltage applied to the voltage division point Pdiv1 is affected by the parasitic component existing from the external resistor Rext through the ZQ pad 201 to the voltage division point Pdiv1, but is not affected by other components.

Therefore, as the parasitic component existing from the external resistor Rext through the ZQ pad 201 to the voltage division point Pdiv1 is minimized, it is possible to minimize a resistance difference between the external resistor Rext and the DQ pin 221.

Since the configuration of the ZQ pin 205 and the wire 203 is necessary, the voltage division point Pdiv1 may be moved to the ZQ pad 201 to exclude the influence caused by the parasitic component existing between the ZQ pad 201 and the comparator 207.

Therefore, as the resistance difference between the external resistor and the DQ pin is minimized, it is possible to provide a semiconductor apparatus capable of performing a stable operation despite a process variation.

Furthermore, as the ZQ pad 201 and the joining interconnection 223 are formed in the same layer, the ZQ pad 201 and the joining interconnection 223 may be formed by a single process when an impedance calibration circuit is manufactured.

While certain embodiments have been described above, it will be understood to those skilled in the art that the embodiments described are by way of example only. Accordingly, the semiconductor apparatus and the impedance calibration circuit described herein should not be limited based on the described embodiments. Rather, the semiconductor apparatus and the impedance calibration circuit described herein should only be limited in light of the claims that follow when taken in conjunction with the above description and accompanying drawings.

What is claimed is:

1. A semiconductor apparatus comprising:
a data input/output circuit; and
an impedance calibration circuit configured to output a code signal for controlling a resistance value of the data input/output circuit in response to a division voltage applied to a joining interconnection directly coupled to a ZQ pad and a preset reference voltage.

2. The semiconductor apparatus according to claim 1, wherein the impedance calibration circuit comprises:
a first pull-up unit coupled to the ZQ pad and configured to apply the division voltage to the ZQ pad in response to the code signal;
the joining interconnection coupled to the ZQ pad; and
a comparator configured to receive the division voltage from the joining interconnection, compare the division voltage with the reference voltage, and output the code signal.

3. The semiconductor apparatus according to claim 2, wherein the first pull-up unit is coupled to the ZQ pad through one or more interconnection layers.

4. The semiconductor apparatus according to claim 2, wherein the comparator is coupled to the ZQ pad through the joining interconnection and one or more interconnection layers.

5. The semiconductor apparatus according to claim 4, wherein the ZQ pad and the joining interconnection are formed in a same layer as an uppermost interconnection layer among the one or more interconnection layers.

6. The semiconductor apparatus according to claim 1, wherein the ZQ pad and the joining interconnection are formed in a same layer.

7. An impedance calibration circuit comprising:
a first pull-up unit coupled to a ZQ pad;
a joining interconnection directly electrically coupled to the ZQ pad; and
a comparator configured to generate a code signal in response to a division voltage applied to the joining interconnection and a preset reference voltage, and provide the generated code signal to the first pull-up unit and a data input/output circuit.

8. The impedance calibration circuit according to claim 7, wherein the ZQ pad and the joining interconnection are formed in a same layer.

9. The impedance calibration circuit according to claim 7, wherein the first pull-up unit is coupled to the ZQ pad through one or more interconnection layers.

10. The impedance calibration circuit according to claim 9, wherein the comparator is coupled to the ZQ pad through the joining interconnection and the one or more interconnection layers.

11. An impedance calibration circuit of a semiconductor apparatus, comprising:
a ZQ pad;
a pull-up unit coupled to the ZQ pad through a first electrical path; and
a comparator coupled to the ZQ pad through a second electrical path, wherein the comparator is configured to compare a voltage, dependent upon the pull-up unit, with a reference voltage, and wherein the first electrical path and the second electrical path have a common node only at the ZQ pad.

12. The impedance calibration circuit according to claim 11, wherein the pull-up unit is coupled to a metal line in the first electrical path.

13. The impedance calibration circuit according to claim 11, wherein the comparator is coupled to a metal line in the second electrical path.

14. The impedance calibration circuit according to claim 11, further comprising:
a first metal line coupled to the ZQ pad;
a second metal line coupled to the first metal line; and
the second metal line coupled to the comparator.

15. The impedance calibration circuit according to claim 14, wherein the first metal line and the ZQ pad are formed in the same layer.
